(19) United States
(12) Patent Application Publication
(10) Pub. No.: US 2015/0054997 A1
(43) Pub. Date: Feb. 26, 2015

(54) IMAGE SENSORS HAVING PIXEL ARRAYS WITH NON-UNIFORM PIXEL SIZES

(71) Applicant: Aptina Imaging Corporation, George Town (KY)

(72) Inventor: Jaroslav Hynecek, Allen, TX (US)

(73) Assignee: Aptina Imaging Corporation, George Town (KY)

(21) Appl. No.: 14/189,311

(22) Filed: Feb. 25, 2014

Related U.S. Application Data
(60) Provisional application No. 61/869,444, filed on Aug. 23, 2013.

(51) Int. Cl. H04N 5/369; H01L 27/146

(52) U.S. Cl. CPC H04N 5/369; H01L 27/14643
USPC 348/302; 257/292

(57) ABSTRACT

An image sensor having an array of pixels and a silicon substrate may be provided. In one embodiment, the array of pixels may have pixels of equal charge storage capacity but with varying sizes and thus varying sensitivities. For example, a first pixel may have a larger charge-generating volume than a second pixel. In another suitable embodiment, the charge storage capacity of the image sensor pixels may be varied while the charge-generating volume remains the same. These configurations are achieved by placing a p+ type doped layer in the silicon substrate close to and parallel to the surface of the array. The p+ type doped layer may include a plurality of openings to allow photo-generated carriers to flow from the silicon bulk to the charge storage wells located near the surface of the substrate.

This application claims the benefit of provisional patent application No. 61/869,444, filed Aug. 23, 2013, which is hereby incorporated by reference herein in its entirety.

### BACKGROUND

This relates to solid-state image sensors and, more specifically, to image sensors having pixel arrays with non-uniform pixel sizes.

Typical image sensors sense light by converting impinging photons into electrons or holes that are integrated (collected) in sensor pixels. After completion of an integration cycle, collected charge is converted into a voltage, which is supplied to the output terminals of the sensor. In CMOS image sensors, the charge to voltage conversion is accomplished directly in the pixels themselves and the analog pixel voltage is transferred to the output terminals through various pixel addressing and scanning schemes. The analog signal can be also converted on-chip to a digital equivalent before reaching the chip output. The pixels have incorporated in them a buffer amplifier, typically a Source Follower (SF), which drives the sense lines that are connected to the pixels by suitable addressing transistors.

After charge to voltage conversion is completed and the resulting signal transferred out from the pixels, the pixels are reset in order to be ready for accumulation of new charge. In pixels that use a Floating Diffusion (FD) as the charge detection node, the reset is accomplished by turning on a reset transistor that conductively connects the FD node to a voltage reference, which is typically the pixel drain node. This step removes collected charge; however, it also generates kTC-reset noise as is well known in the art. This kTC-reset noise is removed from the signal using a Correlated Double Sampling (CDS) signal processing technique in order to achieve the desired low noise performance. CMOS image sensors that utilize a CDS technique usually include three transistors (3T) or four transistors (4T) in the pixel, one of which serves as the charge transferring (Tx) transistor. It is possible to share some of the pixel circuit transistors among several photodiodes, which also reduces the pixel size. An example of a 4T pixel circuit with pinned photodiode can be found in U.S. Pat. No. 5,625,210 to Lee, incorporated herein as a reference.

FIG. 1 is a simplified cross-sectional view of two neighboring pixels (Pixel 1 and Pixel 2) in a typical image sensor 100. As shown in FIG. 1, each image sensor pixel includes a pixel photodiode (PD) that collects photon-generated carriers, a charge transfer gate 110 of a charge transfer transistor, and a floating diffusion 104. The pixel is fabricated in a substrate 101 that has a p+ doped layer 102 deposited on a back surface. The device substrate 101 also includes an epitaxial p-type doped layer 114 situated above the p+ type doped layer 102. The photons that enter this region generate carriers that are collected in the potential well of the photodiode (PD) formed in region 108.

The surface of epitaxial layer 114 is covered by an oxide layer 109 that isolates the doped poly-silicon charge transfer gate Tx 110 from the substrate. The PD is formed by an n-type doped layer 108 and a p+ type doped potential pinning layer 107.

The FD diode 104 that senses charge transferred from the PD is connected to the pixel source follower SF transistor (not shown). The FD, SF, and the remaining pixel circuit components are all built in the p-type doped well 103 that diverts the photon generated charge into the photodiode potential well located in layer 108. The pixels are isolated from each other by p+ type doped regions 105 and 106, which may extend all the way to the p+ type doped layer 102 and by the shallow p+ type doped implanted regions 115 that are typically aligned directly above regions 105 and 106 and implanted through the same mask. The whole pixel is covered by several inter-level (IL) oxide layers 112 (only one is shown in FIG. 1) that are used for pixel metal wiring and interconnect isolation. The pixel active circuit components are connected to the wiring by metal via plugs 113 deposited through contact holes 111. As shown in FIG. 1, Pixel 1 and Pixel 2 have equal charge storage capacity and charge-generating regions of equal size.

Pixels such a Pixel 1 and Pixel 2 of FIG. 1 are typically arranged in a uniform array of the type shown in FIG. 2. FIG. 2 shows a top view of image sensor 100 of FIG. 1, showing the image sensor focal plane matrix on which the image is projected. In backside illuminated image sensors (as illustrated in FIG. 1), image sensors are illuminated from the back of the silicon substrate while the pixel circuits are located on the front of the substrate. Backside sensor illumination reduces the light loss that can occur due to pixel wiring in front side illuminated image sensors and thus increases quantum efficiency.

Typically, image sensors sense color by including various color filters and microlenses on the back of the substrate to make the pixels sensitive to predetermined bands of the electromagnetic spectrum. A typical color filter and microlens arrangement is shown in FIG. 2. As shown in FIG. 2, pixels 201 and 204 have green color filters placed on them, while pixels 202 and 203 have blue and red color filters place on them, respectively. This type of arrangement is known in the industry as a Bayer color filter scheme.

While this concept works reasonably well, it also has several problems. For example, the color filters typically have different absorption coefficients, which results in uneven pixel saturation and thus a sacrifice of some pixel dynamic range. This is typically corrected by adjusting the filter thicknesses.

The Bayer color filter scheme also sacrifices approximately ⅔ of the photons that fall on the sensor, which results in poor low light level sensitivity. This has been recently countered by eliminating one of the green filters. For example, green filter 204 may be replaced with a clear layer to improve low light sensitivity. However, now that the clear pixel collects photons of all colors, it saturates at much lower light intensities than the rest of the pixels in the sensor. For normal light intensities, the information from this pixel is often discarded, which affects the sensor resolution.

It would therefore be desirable to be able to provide image pixel arrays with improved dynamic range, color response, and sensitivity that saturate uniformly.

### BRIEF DESCRIPTION OF THE DRAWINGS

FIG. 1 is a simplified cross-sectional side view of two neighboring conventional image sensor pixels.

FIG. 2 is a top view of a conventional pixel layout that uses a Bayer color filter scheme with the two green filters, one red filter, and one blue filter in a group of four pixels and in which all of the pixels, microlenses, and color filters have the same size and are arranged in a uniform grid pattern.

FIG. 3 is a simplified cross-sectional side view of illustrative image sensor pixels having a bottom p+ type doped (BTP) layer with openings and having deep pixel saturation implants that define pixel regions of different sizes in accordance with an embodiment of the present invention.

FIG. 4 is a top view of an illustrative pixel layout having a pattern of red, green, blue, and clear color filters and having pixels of different sizes to balance pixel sensitivity so that pixels are saturated at the same light level in accordance with an embodiment of the present invention.

FIG. 5 is a top view of an illustrative pixel layout having a pattern of red, green, blue, and clear color filters and having pixels of different sizes to increase sensitivity in low light level conditions in accordance with an embodiment of the present invention.

FIG. 6 is a simplified cross-sectional side view of illustrative image sensor pixels having a bottom p+ type doped (BTP) layer with openings and having photodiodes with different storage capacities in accordance with an embodiment of the present invention.

FIG. 7 is a top view of an illustrative pixel layout having a pattern of red, green, blue, and clear color filters and having pixels of the type shown in FIG. 6 arranged in a uniform grid in accordance with an embodiment of the present invention.

FIG. 8 is a block diagram of a system employing the embodiments of FIGS. 2-7 in accordance with an embodiment of the present invention.

### DETAILED DESCRIPTION

Electronic devices such as digital cameras, computers, cellular telephones, and other electronic devices include image sensors that gather incoming light to capture an image. The image sensors may include arrays of image sensor pixels (sometimes referred to as pixels or image pixels). The image pixels in the image sensors may include photosensitive elements such as photodiodes that convert the incoming light into electric charge. The electric charge may be stored and converted into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the image pixels and readout circuitry for reading out image signals corresponding to the electric charge generated by the photosensitive elements.

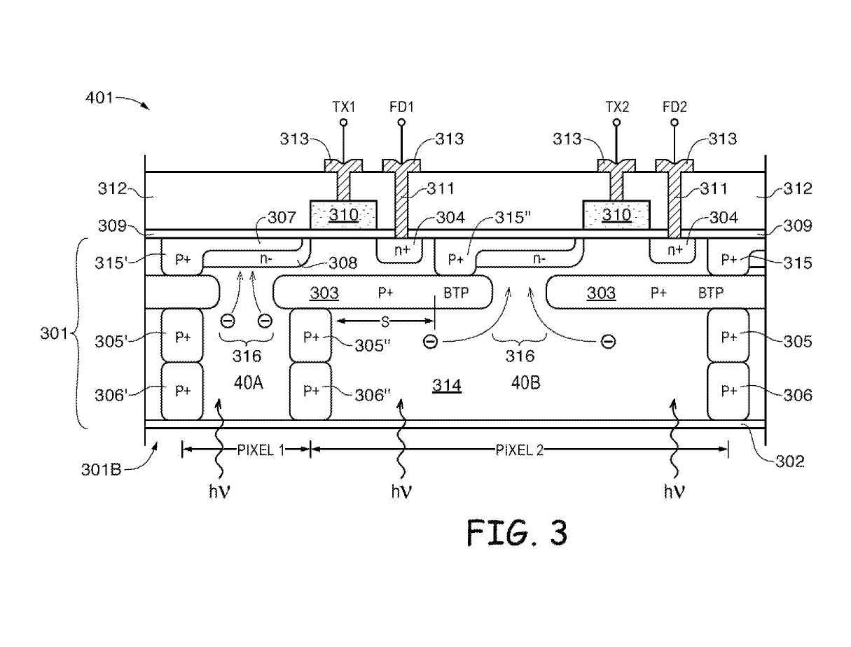

Image sensor pixels in an image sensor pixel array may have non-uniform sizes. For example, image sensor pixels may be designed to have different sizes and thus different sensitivities. Sensitivities may, if desired, be adjusted to match a particular color filter scheme. A simplified cross-sectional side view of a portion of an image pixel array having pixels of different sizes is shown in FIG. 3. As shown in FIG. 3, pixel array 401 may include two neighboring pixels, Pixel 1 and Pixel 2, formed in a device substrate such as silicon substrate 301. Substrate 301 may include a p+ type doped layer 302 and an epitaxial layer such as epitaxial layer 314 (e.g., a p-type or n-type doped epitaxial layer) situated above p+ type doped layer 302. Photons that enter this region may generate carriers that are collected in the potential well of the photodiode (PD) formed in region 308. The use of p+ type doped layer 302 may help prevent the generation of excessive dark current by the interface states.

The surface of epitaxial layer 314 may be covered by an oxide layer such as oxide layer 309. Oxide layer 309 may be used to isolate a doped poly-silicon charge transfer (Tx) gate such as charge transfer gate 310 from substrate 301. The PD is formed by n-type doped layer 308 and p+ type doped potential pinning layer 307, which may help reduce the interface states generated dark current (similarly to p+ type doped layer 302). Each pixel includes a floating diffusion (FD) such as n+ type doped floating diffusion 304.

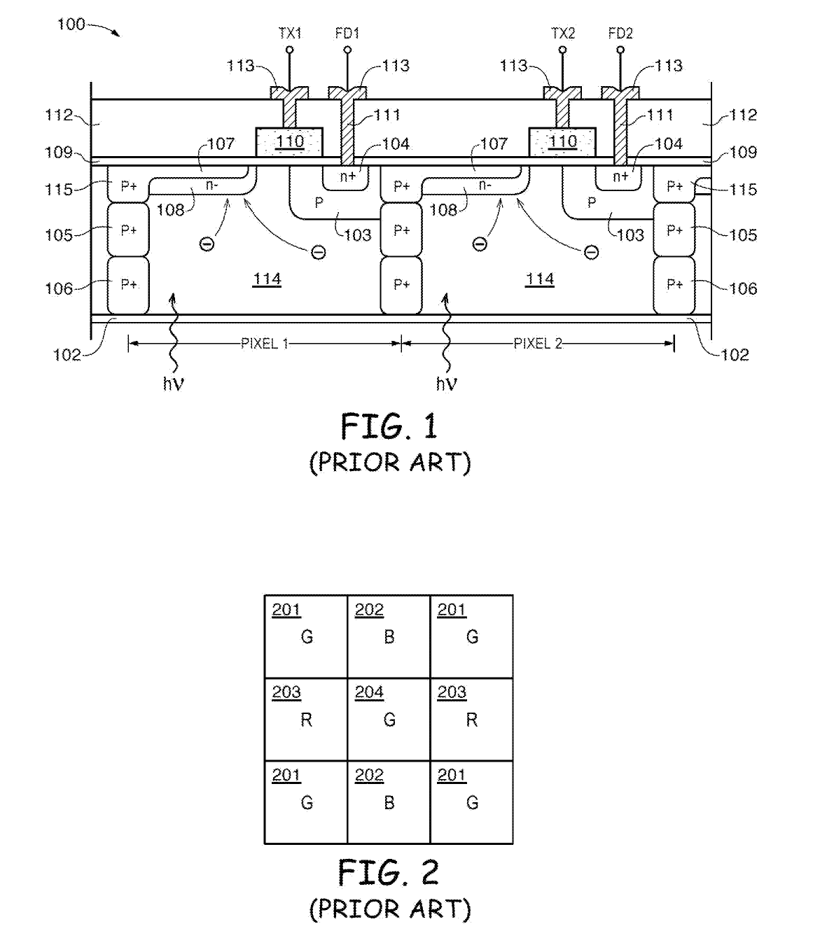

Each FD diode 304 is connected to a pixel source follower (SF) transistor and a reset transistor (not shown), and each FD is configured to sense charge transferred from the PD. The FD, SF, and the remaining pixel circuit components that are formed in the top region of the substrate are now separated from the silicon bulk by a bottom p+ type doped layer (BTP) 303. This is substantially different from the arrangement of FIG. 1 where the pixel circuit components are built in p-type doped well 103.

As shown in FIG. 3, BTP layer 303 may include built-in openings 316 that allow photo-generated carriers (e.g., electrons) to flow from the bulk of the silicon into the PDs and to be stored in the potential wells of the pixels in regions 308. BTP layer 303 may therefore serve several purposes. It provides efficient shielding of pixel circuits and of FD 304 from the carriers generated in the silicon bulk by diverting them into the appropriate storage wells. This function is similar to the function of p-type doped well 103 in the case of FIG. 1. The presence of BTP layer 303 also improves the pixel well capacity in pixel array 401. However, BTP layer 303 now also serves to partition the silicon bulk into different size regions by allowing deep p+ type doped pixel separation implants 305 and 306 to be out of vertical alignment with shallow p+ type doped pixel separation implants 315. For example, as shown in FIG. 3, deep p+ type doped pixel separation implants 305′ and 306′ may be aligned with shallow p+ type doped pixel separation implant 315′, whereas deep p+ type doped pixel separation implants 305″ and 306″ may be offset from shallow p+ type doped pixel separation implant 315″ by a distance S. This allows charge-generating region 40A of Pixel 1 to be smaller than charge-generating region 40B of Pixel 2 (in this example).

In this type of arrangement, the pixel charge storage regions may be built with identical sizes while the pixel charge-generating regions may have different sizes, thereby resulting in pixels that have equal charge storage capacity but different sensitivities.

In addition to improving the pixel well capacity, BTP layer 303 may also allow more flexibility in the design of transfer gate 310. For example, a stronger body effect may help prevent charge transfer transistor punch-through, which in turn allows the gate length of transfer gate 310 to be shorter (if desired). BTP layer 303 may be located very close to the silicon surface, thereby minimizing the silicon volume in which stray carriers can be generated by longer wavelength light that has not been completely absorbed in the underlying silicon bulk. This effect can be minimized by optimizing the thickness of epitaxial layer 314 in comparison to the thickness of the remaining silicon above BTP layer 303. This is particularly advantageous for pixels that are designed with additional charge carrier storage sites (not shown) and that operate in global shutter mode.

The whole pixel surface may be covered by several inter-level (IL) oxide layers 312 (only one is shown here) that are used for the pixel metal wiring and interconnect isolation. The pixel active circuit components are connected to the wiring by metal vias 313 (sometimes referred to as metal plugs) deposited through contact via holes 311.

The example of FIG. 3 in which pixel array 401 includes a p-type doped epitaxial layer, p+ type doped pixel separation regions, p+ type pinning layers, and n+ type doped junctions, is merely illustrative. If desired, the polarities of all the doped regions may be reversed to instead use an n-type doped epitaxial layer, n+ type doped pixel separation regions, n+ type doped pinning layers, and p+ type doped junctions. Configurations with the doping of FIG. 3 are described herein as an example.

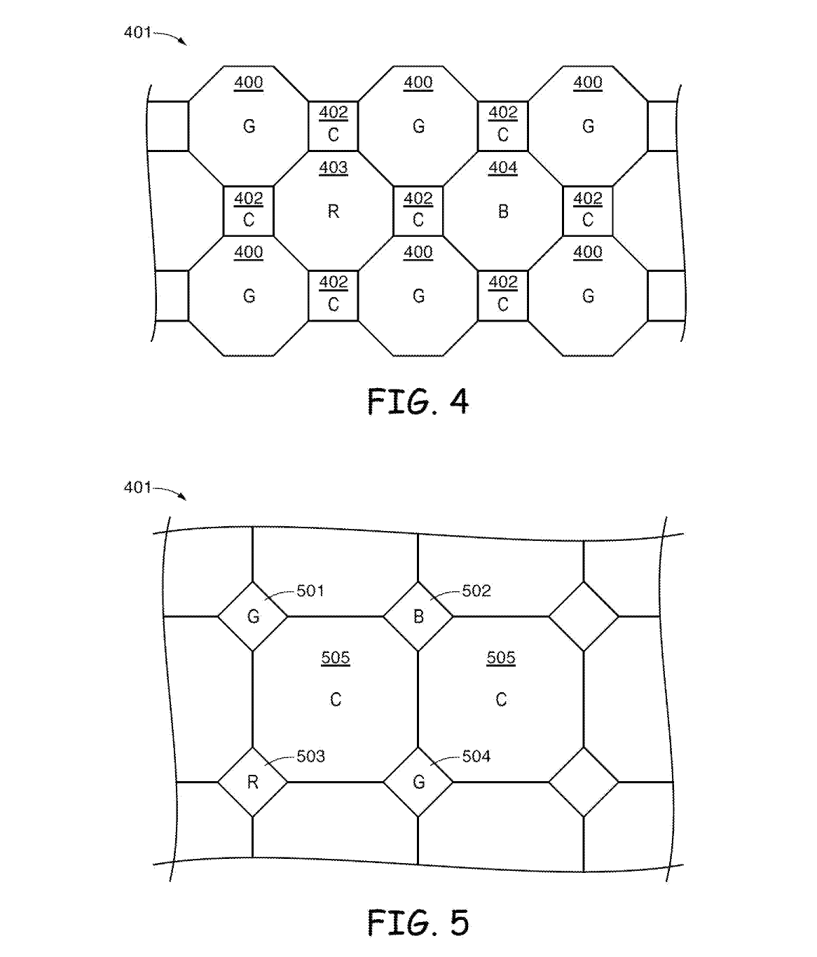

There are now several ways to arrange the color filters and microlenses on the back of substrate 301 (e.g., back surface 301B of substrate 301). FIG. 4 illustrates an exemplary pixel layout that may be used with pixels of the type shown in FIG. 3. As shown in FIG. 4, pixel array 401 may include larger octagonal shaped regions 400, 403, and 404 that include green, red, and blue color filters, respectively. These regions are joined together by rectangular (e.g., square) regions 402, which are associated with clear pixels. If desired, clear pixel regions 402 may include just microlenses without any color filters. In the illustrative example of FIG. 4, clear pixels 402 may correspond to smaller pixels in array 401 such as Pixel 1 of FIG. 3, whereas color pixels 400, 403, and 404 may correspond to larger pixels in array 401 such as Pixel 2 of FIG. 3.

If desired, clear pixels such as pixels 402 may include filters that pass two or more colors of light (e.g., two or more colors of light selected from the group that includes red light, blue light, and green light). These filters may sometimes be referred to as “broadband” or “complementary” filter elements. For example, yellow color filter elements that are configured to pass red and green light and clear color filter elements that are configured to pass red, green, and blue light may both be referred to as broadband filters or broadband color filter elements. Similarly, image pixels that include a broadband filter (e.g., a yellow or clear color filter) and that are therefore sensitive to two or more colors of light (e.g., two or more colors of light selected from the group that includes red light, blue light, and green light) may sometimes be referred to as broadband pixels or broadband image pixels. In contrast, “colored” pixel may be used to refer to image pixels that are primarily sensitive to one color of light (e.g., red light, blue light, green light, or light of any other suitable color).

The sizes of regions 400, 402, 403, and 404 may be adjusted to balance the sensitivities of these pixels in accordance with their filter in-band and out-of-band absorption characteristics. For example, the sizes of pixels in pixel array 401 may be adjusted such that pixel charge saturation for a given light intensity and color temperature occur at the same level for all pixels. This improves sensor resolution, dynamic range, and sensitivity.

FIG. 5 illustrates another exemplary pixel layout that may be used with pixels of the type shown in FIG. 3. As shown in FIG. 5, pixel array 401 may include larger octagonal shaped regions 505 and smaller rectangular (e.g., square) regions 501, 502, 503, and 504. Larger pixel regions 505 may be associated with broadband (e.g., clear) pixels and may, if desired, include microlenses without any color filters or may include broadband filters. Smaller pixel regions 501, 502, 503, and 504 may include green, blue, red, and green color filters, respectively, arranged in a Bayer-like arrangement. In this illustrative example, clear pixels 505 may correspond to larger pixels in array 401 such as Pixel 2 of FIG. 3, whereas color pixels 501, 502, 503, and 504 may correspond to smaller pixels in array 401 such as Pixel 1 of FIG. 3.

In the type of arrangement of FIG. 5, larger pixels such as pixels 505 may be used to provide a signal in low light level illumination, while smaller pixels such as pixels 501, 502, 503, and 504 may be used to supply a color signal. If desired, larger pixels 505 may include complementary color filters and may be used to supply a color signal in low light level illuminations. Because smaller pixels have lower sensitivity, saturation will occur at higher illumination levels, which significantly extends the sensor dynamic range. This is an important advantage when an image sensor operates in global shutter mode because there is no time skew in charge integration of large and small pixel signals.

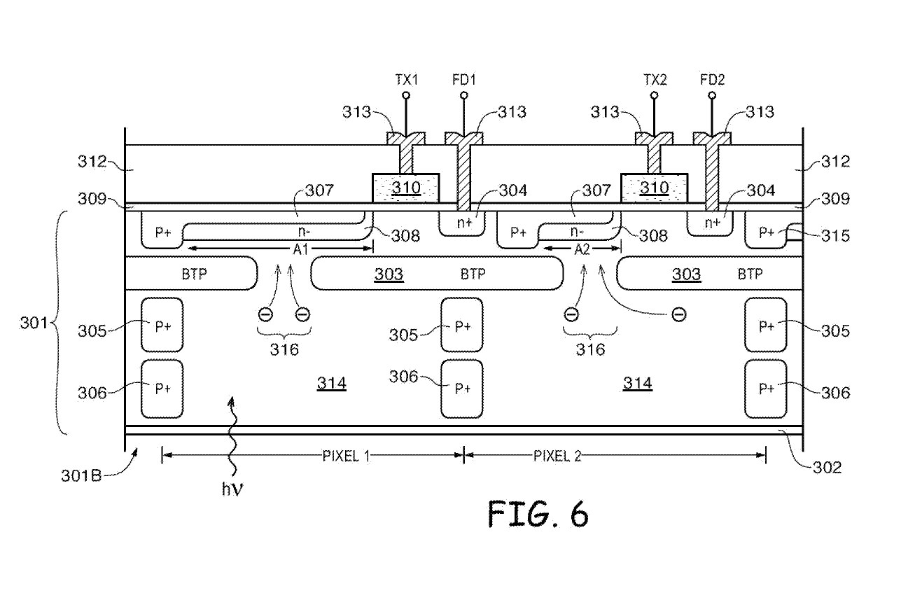

In the configurations of FIGS. 3-5, pixels in pixel array 401 have charge-generating regions of different sizes while the charge storage area in each pixel is has a uniform size across the array. This is merely illustrative, however. If desired, pixel array 401 may be designed such that the pixel charge-generating region is uniform across the array while the size of the charge storage area is varied (i.e., non-uniform) across the array. This type of arrangement is shown in FIG. 6. As shown in FIG. 6, Pixel 1 and Pixel 2 have charge-generating regions of equal volumes, but the storage areas of Pixel 1 and Pixel 2 have different sizes. For example, the photodiode of Pixel 1 may have a charge storage area A1 that is smaller than the charge storage area A2 of the photodiode of Pixel 2. Arrangements of the type shown in FIG. 6 may be useful in balancing pixel saturation levels with pixels of different spectral responses. In some cases, it may also be advantageous to fabricate color filters and microlenses that all have the same size.

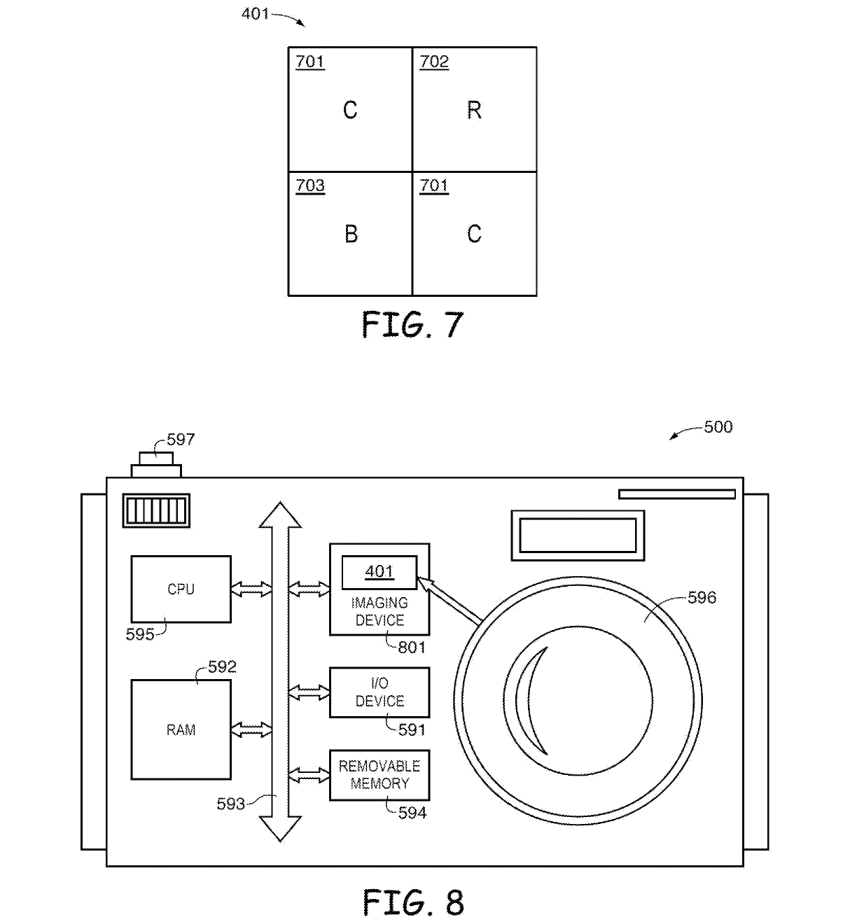

FIG. 7 illustrates an exemplary pixel layout that may be used with pixels of the type shown in FIG. 6. As shown in FIG. 7, pixel array 401 may include pixel regions 702 and 703 that include color filters such as red and blue color filters, whereas pixel regions 701 may not include a filter or may include a broadband filter. Pixel regions 701 may therefore be associated with broadband (e.g., clear) pixels. In this type of arrangement, all of the pixels in array 401 have the same size (e.g., the charge-generating regions, color filters, and microlenses may all have the same size).

In order to balance pixel saturation levels in pixel array 401, pixels with color filters such as pixels 702 and 703 may have photodiodes with smaller storage areas, while broadband pixels (e.g., clear pixels 701) may have photodiodes with larger storage areas. For example, color pixels 702 and 703 may correspond to Pixel 2 of FIG. 6, whereas broadband pixels 701 may correspond to Pixel 1 of FIG. 6. This is, however, merely illustrative. If desired, the storage capacity of color pixels may be larger than that of clear pixels.

FIG. 8 shows in simplified form a typical processor system 500, such as a digital camera, which includes an imaging device 801. Imaging device 801 may include a pixel array 401 having pixels of the type shown in FIG. 3 or 6 formed on an image sensor SOC. Processor system 500 is exemplary of a system having digital circuits that may include imaging device 801. Without being limiting, such a system may include a computer system, still or video camera system, scanner, machine vision, vehicle navigation, video phone, surveillance system, auto focus system, star tracker system, motion detection system, image stabilization system, and other systems employing an imaging device.

Processor system 500, which may be a digital still or video camera system, may include a lens such as lens 596 for focusing an image onto a pixel array such as pixel array 401 when shutter release button 597 is pressed. Processor system 500 may include a central processing unit such as central processing unit (CPU) 595. CPU 595 may be a microprocessor that controls camera functions and one or more image flow functions and communicates with one or more input/output (I/O) devices 591 over a bus such as bus 593. Imaging device 801 may also communicate with CPU 595 over bus 593. System 500 may include random access memory (RAM) 592 and removable memory 594. Removable memory 594 may include flash memory that communicates with CPU 595 over bus 593. Imaging device 801 may be combined with CPU 595, with or without memory storage, on a single integrated circuit or on a different chip. Although bus 593 is illustrated as a single bus, it may be one or more buses or bridges or other communication paths used to interconnect the system components.

Various embodiments have been described illustrating image pixel arrays with non-uniform pixel sizes. This is accomplished by incorporating a special p+ type doped BTP layer under the whole pixel array and by providing the BTP layer with openings to allow photo-generated carriers to flow from the silicon bulk to the PD regions. The presence of the BTP layer allows flexibility in the placement of the deep pixel separation implants. For example, the pixel separation implants can be placed at varying distances from each other to individually adjust pixel charge collection volume and thereby adjust the pixel sensitivity. If desired, the storage area of the pixels may remain uniform throughout the array.

Image pixel arrays having pixels of different sizes may adjust pixel sensitivity according to the color filter layout of the pixel array. For example, broadband pixels that are sensitive to a larger band of wavelengths of light may be made smaller than color pixels that are sensitive to a smaller band of wavelengths of light. In another suitable arrangement, broadband pixels may be made larger than color pixels.

If desired, a pixel array may be designed such that the storage area of pixels is varied while the charge-generating volume remains uniform across the array. For example, broadband pixels that are sensitive to a larger band of wavelengths of light may have a larger charge storage area than color pixels that are sensitive to a smaller band of wavelengths of light.

The foregoing embodiments are intended to be illustrative and not limiting; it is noted that persons skilled in the art can make modifications and variations in light of the above teachings. It is therefore to be understood that changes may be made in the particular embodiments of the invention disclosed, which are within the scope and spirit of the invention as defined by the appended claims. The foregoing is merely illustrative of the principles of this invention which can be practiced in other embodiments.

What is claimed is:

1. An image sensor having an array of image sensor pixels and a silicon substrate, the image sensor comprising:
a plurality of photodiodes formed in a surface of the silicon substrate, wherein the silicon substrate includes a bulk portion under the plurality of photodiodes;
a p+ type doped layer that extends under the plurality of photodiodes parallel to the surface, wherein the p+ type doped layer comprises a plurality of openings through which charge carriers pass from the bulk portion of the silicon substrate to the photodiodes; and
a plurality of pixel separation implants that separate the bulk portion of the silicon substrate into a plurality of charge-generating regions in which charge carriers are generated, wherein each photodiode collects charge carriers that are generated in a respective one of the charge-generating regions, and wherein at least two of the charge-generating regions have different sizes.

2. The image sensor defined in claim 1 wherein the size of each charge-generating region is defined by the locations of the pixel separation implants.

3. The image sensor defined in claim 2 wherein the plurality of photodiodes all have the same charge storage area.

4. The image sensor defined in claim 2 wherein the at least two charge-generating regions comprise first and second charge-generating regions that correspond respectively to first and second image sensor pixels in the array of image sensor pixels, wherein the first image sensor pixel includes a color filter, and wherein the second image sensor pixel includes a broadband color filter.

5. The image sensor defined in claim 4 wherein the first charge-generating region associated with the first image sensor is larger than the second charge-generating region associated with the second image sensor pixel.

6. The image sensor defined in claim 4 wherein the first charge-generating region associated with the first image sensor pixel is smaller than the second charge-generating region associated with the second image sensor pixel.

7. The image sensor defined in claim 2 wherein the at least two charge-generating regions comprise first and second charge-generating regions that correspond respectively to first and second image sensor pixels in the array of image sensor pixels, wherein the first image sensor pixel has a color filter corresponding to a primary color, and wherein the second image sensor pixel has a color filter corresponding to a complementary color.

8. The image sensor defined in claim 7 wherein the first-charge generating region is larger than the second charge-generating region.

9. The image sensor defined in claim 2 wherein the at least two charge-generating regions comprise first and second charge-generating regions that correspond respectively to first and second image sensor pixels in the array of image sensor pixels, wherein the first image sensor pixel has a rectangular shape, and wherein the second image sensor pixel has an octagonal shape.

10. An image sensor having an array of image sensor pixels and a silicon substrate, the image sensor comprising:
a plurality of photodiodes formed in a surface of the silicon substrate, wherein the silicon substrate includes a bulk portion under the plurality of photodiodes and wherein at least two of the photodiodes have charge storage areas of different sizes;
a p+ type doped layer that extends under the plurality of photodiodes parallel to the surface, wherein the p+ type doped layer comprises a plurality of openings through which charge carriers pass from the bulk portion of the silicon substrate to the photodiodes; and
a plurality of pixel separation implants that separate the bulk portion of the silicon substrate into a plurality of charge-generating regions in which charge carriers are generated.

11. The image sensor defined in claim 10 wherein each photodiode collects charge carriers that are generated in a respective one of the charge-generating regions.

12. The image sensor defined in claim 11 wherein the charge-generating regions all have the same size.

13. The image sensor defined in claim 10 wherein the at least two photodiodes comprise first and second photodiodes corresponding respectively to first and second image sensor pixels in the image sensor pixel array, wherein the first image sensor pixel includes a color filter, and wherein the second image sensor pixel includes a broadband color filter.

14. The image sensor defined in claim 13 wherein the charge storage area of the first photodiode associated with the first image sensor pixel is smaller than the charge storage area of the second photodiode associated with the second image sensor pixel.

15. A system, comprising:
a central processing unit;
memory;
input-output circuitry; and
an image sensor, wherein the image sensor includes an array of image sensor pixels and a silicon substrate, the image sensor comprising:
a plurality of photodiodes formed in a surface of the silicon substrate, wherein the silicon substrate includes a bulk portion under the plurality of photodiodes;
a p+ type doped layer that extends under the plurality of photodiodes parallel to the surface, wherein the p+ type doped layer comprises a plurality of openings through which charge carriers pass from the bulk portion of the silicon substrate to the photodiodes; and
a plurality of pixel separation implants that separate the bulk portion of the silicon substrate into a plurality of charge-generating regions in which charge carriers are generated, wherein each photodiode collects charge carriers that are generated in a respective one of the charge-generating regions, and wherein at least two of the charge-generating regions have different sizes.

16. The system defined in claim 15 wherein the size of each charge-generating region is defined by the locations of the pixel separation implants.

17. The system defined in claim 16 wherein the plurality of photodiodes all have the same charge storage area.

18. The system defined in claim 16 wherein the at least two charge-generating regions comprise first and second charge-generating regions that correspond respectively to first and second image sensor pixels in the array of image sensor pixels, wherein the first image sensor pixel includes a color filter, and wherein the second image sensor pixel includes a broadband color filter.

19. The system defined in claim 18 wherein the first charge-generating region associated with the first image sensor pixel is larger than the second charge-generating region associated with the second image sensor pixel.

20. The system defined in claim 18 wherein the first charge-generating region associated with the first image sensor pixel is smaller than the second charge-generating region associated with the second image sensor pixel.
